(19) United States
(12) Patent Application Publication
(10) Pub. No.: US 2025/0001433 A1
(43) Pub. Date: Jan. 2, 2025

(54) SUBSTRATE TREATING APPARATUS AND SUBSTRATE TREATING SYSTEM

(71) Applicant: Samsung Electronics Co., Ltd., Suwon-si (KR)

(72) Inventors: Suk Min CHOI, Suwon-si (KR); Yun Seok CHOI, Suwon-si (KR); Byoung Chaul SON, Anseong-si (KR); Dong Cheol SIM, Suwon-si (KR); Jae Sun KIM, Suwon-si (KR); Jae Hyun SUNG, Suwon-si (KR); Eun Seok LEE, Suwon-si (KR)

(73) Assignees: Samsung Electronics Co., Ltd., Suwon-si (KR); KCTECH CO.,LTD., Anseong-si (KR)

(21) Appl. No.: 18/428,946

(22) Filed: Jan. 31, 2024

(30) Foreign Application Priority Data
Jun. 27, 2023 (KR) 10-2023-0082311

(51) Int. Cl. B03C 1/30; B24B 37/34

(52) U.S. Cl. CPC B03C 1/30; B24B 37/34; B03C 2201/20

(57) ABSTRACT

A substrate treating apparatus in which foreign substances are reduced by using a foreign substance collecting unit includes a magnetic structure. The substrate treating apparatus includes a roller configured to be disposed on a rail extending in a first direction and attached to a side surface of a carrier unit to move along the rail, and a foreign substance collecting unit installed on the side surface of the carrier unit, moving together with the roller, and configured to be spaced apart from the rail when the roller is disposed on the rail, wherein the foreign substance collecting unit includes a magnetic structure for adsorbing foreign magnetic substances using a magnetic force, and a case surrounding the magnetic structure.

### CROSS-REFERENCE TO RELATED APPLICATION

This application claims priority to Korean Patent Application No. 10-2023-0082311 filed on Jun. 27, 2023 in the Korean Intellectual Property Office, the contents of which in its entirety are herein incorporated by reference.

### BACKGROUND

### 1. Technical Field

The present disclosure relates to a substrate treating apparatus and a substrate treating system.

### 2. Description of the Related Art

As semiconductor devices are manufactured by integrating fine circuit lines at a high density, corresponding precision polishing is performed on a wafer surface. In order to more precisely polish the wafer, a chemical mechanical polishing process (CMP process) in which chemical polishing as well as mechanical polishing is performed in parallel is performed.

When foreign substances are present on a wafer, the wafer may be damaged in the chemical mechanical polishing process. In order to prevent such damage to the wafer, a cleaning process for cleaning a polished surface of the wafer is performed in several steps. The foreign substances may be generated due to friction while an apparatus for a substrate moves on a rail. As a result, the foreign substances floating in the equipment may exist despite the cleaning process.

Therefore, there is a need for an apparatus for treating a substrate capable of removing foreign substances generated between the apparatus for treating a substrate and the rail.

### SUMMARY

Aspects of the present disclosure provide a substrate treating apparatus in which foreign substances are reduced by using a foreign substance collecting unit including a magnetic structure.

Aspects of the present disclosure also provide a substrate treating system in which foreign substances are reduced by using a foreign substance collecting unit including a magnetic structure.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to some embodiments of the present disclosure, a substrate treating apparatus includes a roller configured to be disposed on a rail extending in a first direction and attached to a side surface of a carrier unit to move along the rail, and a foreign substance collecting unit installed on the side surface of the carrier unit, moving together with the roller, and configured to be spaced apart from the rail when the roller is disposed on the rail, wherein the foreign substance collecting unit includes a magnetic structure for adsorbing magnetic foreign substances using a magnetic force, and a case surrounding the magnetic structure.

According to some embodiments of the present disclosure, a substrate treating apparatus includes a carrier unit configured to adsorb a substrate and configured to connect to a rail for moving the substrate to a polishing pad, a roller installed on a side surface of the carrier unit and configured to move along the rail, a cartridge installed on the side surface of the carrier unit and configured to provide lubricant to the roller, and a foreign substance collecting unit coupled to the cartridge and including a magnetic structure for adsorbing magnetic foreign substances using a magnetic force and a case surrounding the magnetic structure.

According to some embodiments of the present disclosure, a substrate treating system includes a polishing part including a polishing pad disposed on a polishing unit, a carrier unit including a carrier head adsorbing a substrate and moving the substrate to the polishing pad, a rail installed in the polishing part, a roller installed on a side surface of the carrier unit to move along the rail, a cartridge installed on the side surface of the carrier unit and providing lubricant to the roller, and a foreign substance collecting unit coupled onto the cartridge and including a magnetic structure for adsorbing foreign substances using a magnetic force and a case surrounding the magnetic structure, wherein a lower surface of a bottom piece of the case surrounds an upper portion of the rail.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a view for describing a substrate treating system according to some exemplary embodiments.

FIG. 2 is a view for describing a substrate treating apparatus according to some exemplary embodiments.

FIG. 3 is a view for describing a substrate treating apparatus according to some exemplary embodiments.

FIGS. 4 and 5 are views for describing a foreign substance collecting unit illustrated in FIG. 3.

FIG. 6 is an exploded perspective view for describing the foreign substance collecting unit according to some exemplary embodiments.

FIG. 7 is a cross-sectional perspective view for describing a case of the foreign substance collecting unit of FIG. 6.

FIG. 8 is a perspective view for describing a magnetic structure of the foreign substance collecting unit of FIG. 6.

FIG. 9 is a view for describing the magnetic structure of the foreign substance collecting unit of FIG. 6.

FIG. 10 is a cross-sectional perspective view for describing the foreign substance collecting unit used in the substrate treating apparatus according to some exemplary embodiments.

FIG. 11 is a view for describing a substrate treating apparatus according to some exemplary embodiments.

FIGS. 12 and 13 are views for describing the foreign substance collecting unit used in the substrate treating apparatus according to some exemplary embodiments.

FIGS. 14 and 15 are views for describing the foreign substance collecting unit used in the substrate treating apparatus according to some exemplary embodiments.

### DETAILED DESCRIPTION OF THE EMBODIMENTS

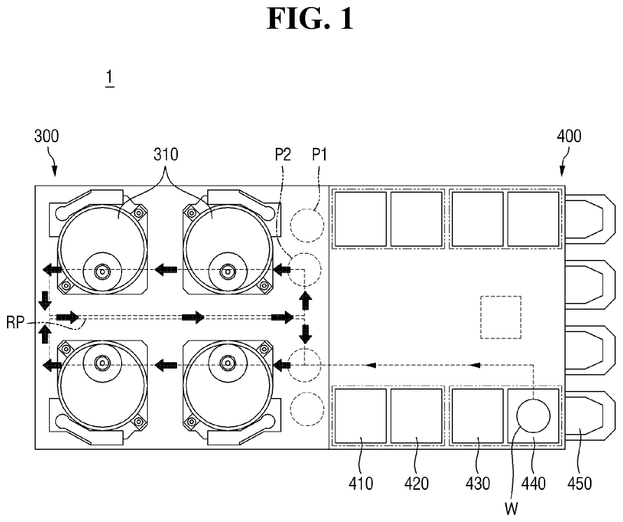

FIG. 1 is a view for describing a substrate treating system according to some exemplary embodiments.

Referring to FIG. 1, a substrate treating system 1 may include a polishing part 300 and a cleaning part 400.

A substrate W may be carried into the substrate treating system 1 by a carry-in/out part 450, which may be, for example, a transfer arm and holder. The substrate W may be loaded into a loading area P2 by a transport robot. The loaded substrate W may be provided to the polishing part 300, also described as a polishing compartment.

The substrate W may be a polishing object that may be polished on a polishing pad 310. The substrate W may have various types and characteristics. The substrate W may be, for example, a wafer used in a semiconductor process.

A plurality of polishing units may be disposed on the polishing part 300. A polishing pad 310 may be attached to each polishing unit. A loading unit may supply the substrate W to the polishing part 300. As the substrate W supplied to the polishing part is in rotational contact with an upper surface of the polishing pad 310 to which a slurry is supplied while attached to a carrier unit 200 moving along a preset path, a chemical mechanical polishing process (CMP) may be performed.

The carrier unit 200 may perform a chemical mechanical polishing process while pressing the substrate to the polishing pad 310 while the substrate is loaded from the loading unit.

The carrier unit 200 may be configured to move along a set circulation path on an area of the polishing part 300. The carrier unit 200 may move along, for example, a rail path RP formed by a rail. The substrate is transported by the carrier unit 200 while being attached to the carrier unit 200.

After the substrate W is polished on the polishing pad 310, the substrate W is transported by the carrier unit 200 and unloaded to an unloading area P1.

Subsequently, the substrate W may be transported to the cleaning part 400 and cleaned. The cleaning part 400, also described as a cleaning compartment, may be disposed to be adjacent to the polishing part 300. The cleaning part 400 may clean foreign substances remaining on a surface of the substrate W.

The cleaning of the substrate W performed in the cleaning part 400 may be a process for cleaning foreign substances remaining on the surface of the substrate W after the polishing process is completed.

The cleaning part 400 may be provided in a structure capable of performing several steps of cleaning and drying processes. A cleaning station constituting the cleaning part 400 may have various structures.

The cleaning part 400 may effectively perform cleaning to remove organic substances and other foreign substances remaining on the surface of the substrate W. The cleaning part 400 may include, for example, contact type cleaning units 410 and 420 that are in physical contact with the surface of the substrate and perform cleaning, and non-contact type cleaning units 430 and 440 that are not in physical contact with the surface of the substrate and perform cleaning. In some exemplary embodiments, the cleaning part 400 may include only one of the contact type cleaning units 410 and 420 and the non-contact type cleaning units 430 and 440.

The contact type cleaning units 410 and 420 may include a first contact type cleaning unit 410 and a second contact type cleaning unit 420. The contact type cleaning units 410 and 420 may include cleaning brushes that rotate on and come into contact with the surface of the substrate W. The substrate W after the polishing process may be cleaned by a pair of cleaning brushes rotating while being rotated by a spindle.

The non-contact type cleaning units 430 and 440 may include a first non-contact type cleaning unit 430 and a second non-contact type cleaning unit 440. The non-contact cleaning units 430 and 440 may be provided in various structures capable of performing cleaning while being not in physical contact with the surface of the substrate W.

The non-contact cleaning units 430 and 440 may perform cleaning by, for example, spraying a cleaning fluid such as chemical, pure water (DIW), steam, or a heterogeneous fluid onto the surface of the substrate W, supplying vibration energy to the surface of the substrate W, or spraying isopropyl alcohol (IPA) onto the surface of the substrate W.

The carry-in/out part 450 of the substrate W may be provided on one side adjacent to the cleaning part 400. The carry-in/out part 450 may be, for example, an equipment front end module (EFEM). The carry-in/out part 450 may carry in a substrate W that needs to be polished and cleaned. The carry-in/out part 450 may carry out the substrate W after polishing and cleaning has been completed.

The substrate W may be carried into the carry-in/out part 450 or may be carried out from the carry-in/out part 450 in a state of being loaded in a front opening unified pod (FOUP). In some cases, it is possible to carry in and out substrates using other storage containers instead of the FOUP, and the present disclosure is not limited by the carry-in/out structure of the substrate.

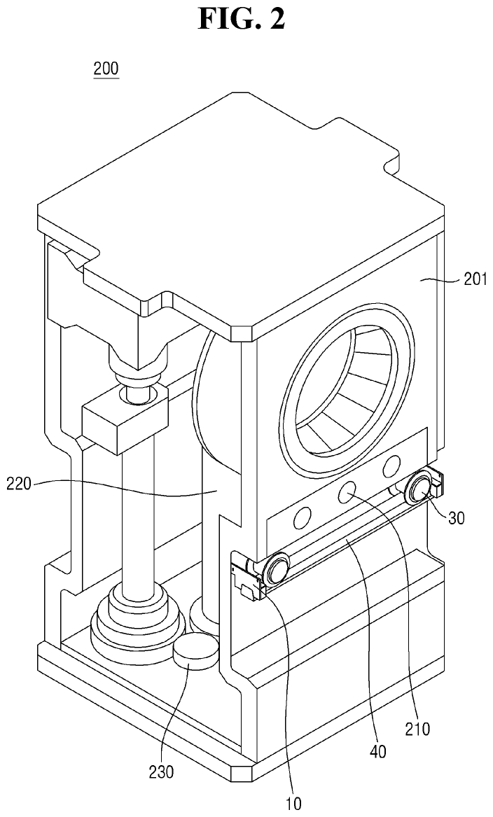

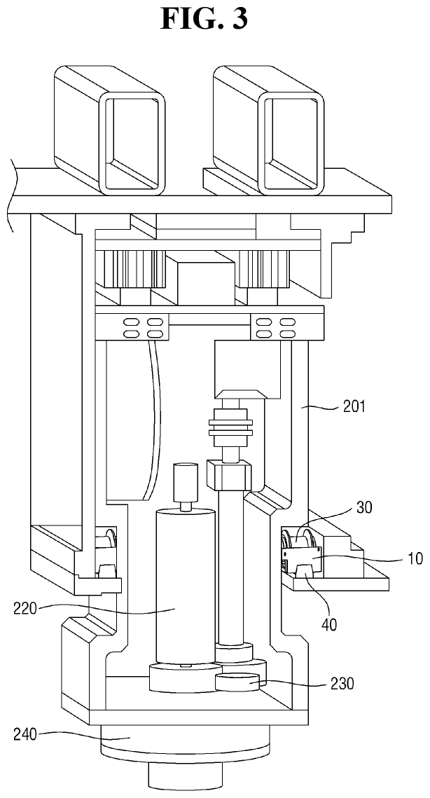

FIG. 2 is a view for describing a substrate treating apparatus according to some exemplary embodiments. FIG. 3 is a view for describing a substrate treating apparatus according to some exemplary embodiments.

Referring to FIGS. 1 to 3, the carrier unit 200 may include a carrier casing 201, a pneumatic port 210, a power converter 230, a carrier head 240, and a roller 30.

The carrier unit 200 may perform a chemical mechanical polishing process while the substrate W is mounted thereon. The carrier unit 200 is provided on the polishing part 300 where the chemical mechanical polishing process for the substrate W is performed. The polishing part 300 may be provided in various structures capable of performing the chemical mechanical polishing process.

The carrier casing 201 may be formed to have a space therein. The carrier casing 201 may protect the inside of the carrier unit 200.

The rollers 30 may be disposed on both (e.g., opposite) sidewalls of the carrier unit 200. Here, opposite sidewalls of the carrier unit 200 may be outer side surfaces of the carrier casing 201. The roller 30 may move along the rail 40. The carrier unit 200 may move along the rail 40 by means of the roller 30. The foreign substance collecting unit 10 may be disposed on one side of the roller 30. The foreign substance collecting unit 10 will be described in detail later.

In some exemplary embodiments, a plurality of rollers 30 may be disposed on each of two sides (e.g., opposite sides) of the carrier casing 201. It is illustrated that two rollers 30 are provided on one side of the carrier unit 200, but the present disclosure is not limited thereto. The foreign substance collecting unit 10 may be disposed on each roller 30.

Although not illustrated, the roller 30 may include an upper roller and a lower roller (e.g., above and below the rail 40) so that the carrier unit 200 moves on the rail 40 without shaking.

The pneumatic port 210 may be formed on the outer side surface of the carrier casing 201. The pneumatic port 210 may be connected to the power converter 230 through a pneumatic supply path 220 inside the carrier casing 201. The pneumatic port 210 may provide air pressure transferred from the outside to the power converter 230.

The power converter 230 may be disposed inside the carrier casing 201. The power converter 230 may convert the air pressure transferred to the pneumatic port 210 into a rotational driving force. Specifically, the power converter 230 may convert the air pressure supplied to the pneumatic port 210 into a driving force for rotating the carrier head 240.

As the power converter 230, a typical conversion means capable of converting the air pressure into the rotational driving force may be used. As the power converter 230, for example, an air motor that converts the air pressure into the rotational driving force may be used.

The air pressure supplied to the pneumatic port 210 may be used to rotate the carrier head 240 during a cleaning process of the carrier head 240. In addition, the air pressure supplied to the pneumatic port 210 may pressurize the substrate W downward during a polishing process of the substrate W.

The carrier head 240 may be mounted on a lower portion of the carrier casing 201. The carrier head 240 may be rotatable. The carrier head 240 may be rotated by the power converter 230. The carrier head 240 may be formed in various structures capable of pressurizing the substrate W.

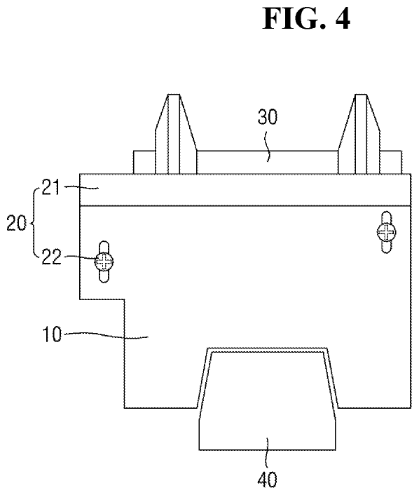

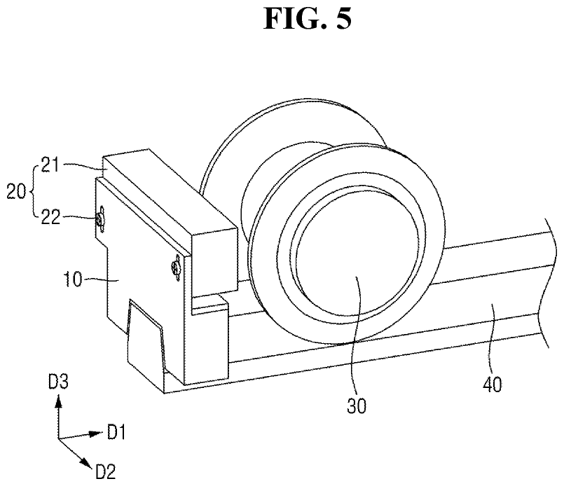

FIGS. 4 and 5 are views for describing a foreign substance collecting unit illustrated in FIG. 3. For convenience of explanation, components except for the foreign substance collecting unit 10, the cartridge 20, the roller 30, and the rail 40 in the substrate treating apparatus of FIG. 3 are omitted.

Referring to FIGS. 3 to 5, the substrate treating apparatus may include a roller 30, a cartridge 20, and a foreign substance collecting unit 10.

The roller 30 may be disposed on the rail 40, and may include a wheel having flanges that keep the roller 30 connected to the rail. The rail 40 may extend in a first direction. The roller 30 may be coupled to the carrier unit 200 (see to FIG. 2), and may be affixed to the carrier unit 200 (e.g., through a connection extending through its axis in the axial direction) to move the carrier unit 200 on the rail 40 in the first direction D1. The rail may be affixed to a wall in the polishing part 300 (see to FIG. 1).

In the present specification, the first direction DI may be a direction in which the rail 40 extends. The second direction D2 may be a direction perpendicular to the first direction D1. The third direction D3 may be a direction perpendicular to the first direction D1 and the second direction D2. The third direction D3 may be a height direction of the foreign substance collecting unit 10.

The cartridge 20 may be installed on a side surface of the carrier unit 200 (e.g., to be affixed to the side surface of the carrier unit 200). The cartridge 20 may be disposed on the rail 40, for example, to cover the rail when the carrier unit 200 moves along the rail. The cartridge 20 may be disposed to be spaced apart from the roller 30 in the first direction D1. For example, the cartridge 20 and the roller 30 do not contact each other.

The cartridge 20 is coupled to the carrier unit 200 and moves together with the roller 30. For example, both the cartridge 20 and the roller 30 are affixed to a side surface of the carrier unit so as to move together along the rail 40 when the carrier unit 200 moves along the rail. Therefore, while the roller 30 moves on the rail 40, a spaced distance between the cartridge 20 and the roller 30 does not change.

The cartridge 20 may provide a lubricant that facilitates the movement of the roller 30. The cartridge 20 may be, for example, an oil cartridge.

The cartridge 20 may include a cartridge cover 21 and a coupling member 22.

In the cartridge 20, after the cartridge cover 21 is separated, the lubricant in the cartridge 20 may be replaced. The cartridge 20 may be a hollow casing, and the cartridge cover 21 may be fixed to the cartridge 20 through the coupling member 22. The coupling member 22 may be, for example, a fastener such as a screw. However, the coupling member 22 is not limited thereto.

The foreign substance collecting unit 10 may be coupled to the cartridge 20. The foreign substance collecting unit 10 may be disposed on the rail 40, for example to cover part of the rail when the carrier unit 200 is placed on the rail. The foreign substance collecting unit 10 may be spaced apart from the rail 40. The foreign substance collecting unit 10 is not in contact with the rail 40. The foreign substance collecting unit 10 may be spaced apart from the roller 30 in the first direction D1. The foreign substance collecting unit 10 is not in contact with the roller 30. The foreign substance collecting unit 10 does not interfere with the movement of the roller 30.

The foreign substance collecting unit 10 may collect foreign substances in the substrate treating apparatus. For example, the foreign substance collecting unit 10 may collect foreign substances generated due to the movement of the roller 30. Such a foreign substance may be, for example, a ferromagnetic material such as iron (Fe). However, the present disclosure is not limited thereto. The foreign substance collecting unit 10 may collect all foreign substances that may be adsorbed using a magnetic force.

Foreign substances may be generated between the roller 30 and the rail 40 due to the movement of the carrier unit 200. The foreign substances may be dispersed according to an air flow in the substrate treating apparatus. The foreign substances may contaminate the substrate by being dispersed into, for example, polishing equipment and cleaning equipment in the substrate treating apparatus. For example, the polishing equipment and the cleaning equipment may correspond to the polishing part 300 and the cleaning part 400 of FIG. 1.

The foreign substance collecting unit 10 may collect foreign substances generated between the roller 30 and the rail 40. The foreign substance collecting unit 10 may be disposed to be adjacent to the roller 30 and the rail 40, and to be in close proximity to the location where the roller contacts the rail, to collect the foreign substances before the foreign substances are dispersed. As a result, the foreign substances in the substrate treating apparatus may be reduced, and process defects of the substrate treating apparatus may be reduced.

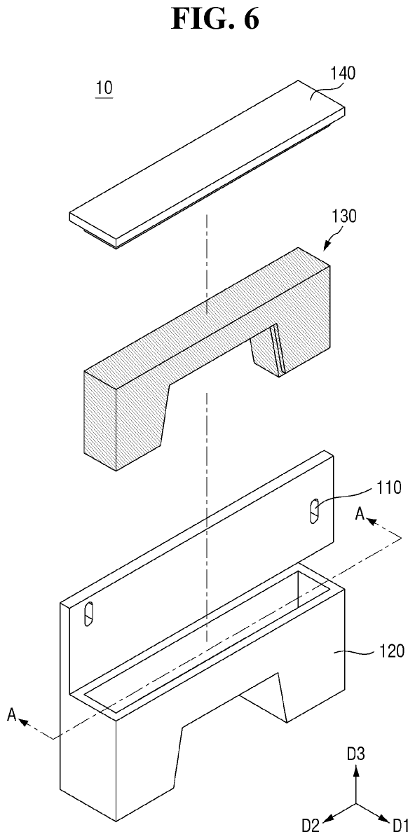

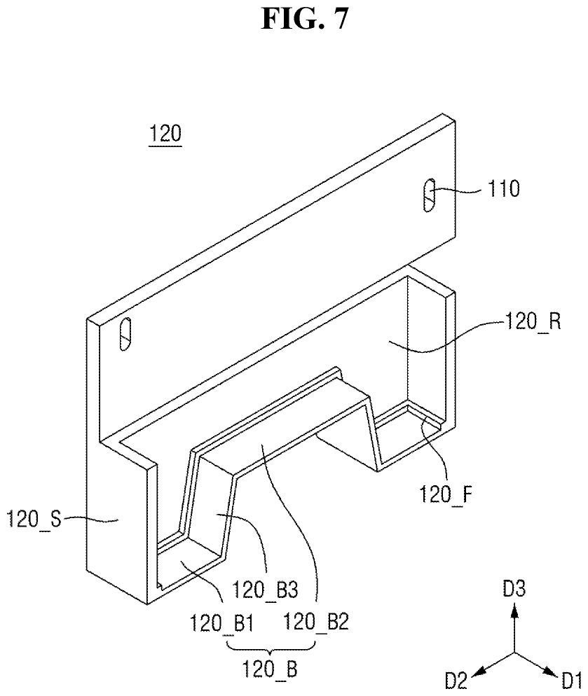

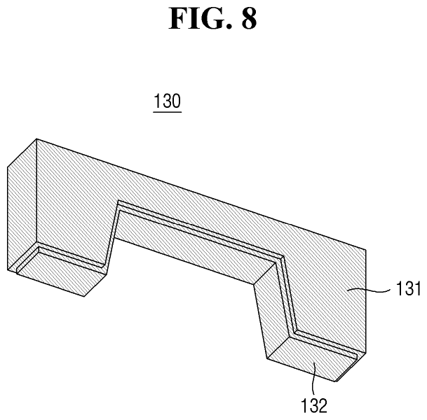

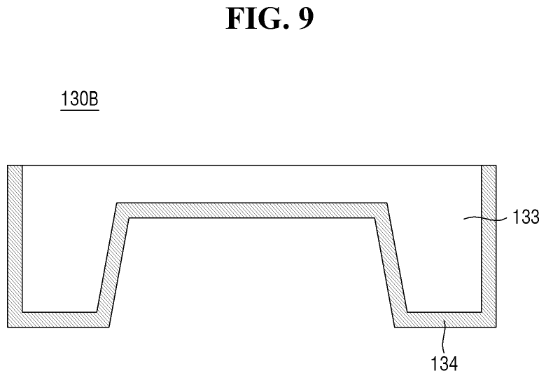

FIG. 6 is an exploded perspective view for describing the foreign substance collecting unit according to some exemplary embodiments. FIG. 7 is a cross-sectional perspective view for describing a case of the foreign substance collecting unit of FIG. 6. FIG. 8 is a perspective view for describing a magnetic structure of the foreign substance collecting unit of FIG. 6. FIG. 9 is a view for describing the magnetic structure of the foreign substance collecting unit of FIG. 6. For reference, FIG. 9 is a cross-sectional perspective view taken along line A-A of FIG. 6.

Referring to FIGS. 5 to 9, in some exemplary embodiments, the foreign substance collecting unit 10 may include a case 120, a magnetic structure 130, and an upper cover 140.

A coupling groove 110 may be formed on an upper portion of the foreign substance collecting unit 10. Specifically, the coupling groove 110 may be formed on a front surface of the case 120. The coupling member 22 is coupled to the coupling groove 110 so that the foreign substance collecting unit 10 and the cartridge 20 may be coupled to each other. The coupling member 22 may simultaneously couple the coupling groove 110 and the cartridge cover. The coupling member 22 may be, for example, a screw. The coupling groove 110 may be, for example, an opening or hole through which a coupling member 22 such as a screw fits.

The coupling groove 110 may have a long shape in the third direction D3. The spaced distance between the foreign substance collecting unit 10 and the rail 40 may be adjusted according to a position of the coupling member 22 coupled to the coupling groove 110. The coupling groove 110 may adjust a height at which the foreign substance collecting unit 10 is coupled to the cartridge 20. Specifically, after the spaced distance (e.g., in a vertical direction) between the foreign substance collecting unit 10 and the rail 40 is set, the coupling member 22 penetrates through the coupling groove 110 and is coupled to the cartridge cover. The foreign substance collecting unit 10 is coupled and fixed to the cartridge 20 by affixing (e.g., screwing) of the coupling member 22. As a result, while the carrier unit 200 moves, the spaced distance between the foreign substance collecting unit 10 and the rail 40 is maintained.

The case 120 may be disposed under the cartridge 20. The case 120 may surround the magnetic structure 130 and form a cover on the magnetic structure 130. The case 120 may have a shape corresponding to the magnetic structure 130, to be conformably formed on the magnetic structure 130. The case 120 may support the magnetic structure 130. The case 120 may prevent the magnetic structure 130 from falling onto the rail 40. The case 120 may cover side surfaces and an upper surface of the rail 40.

In some exemplary embodiments, the case 120 may include side walls 120_S, a bottom piece 120_B, and a frame 120_F. The side walls 120_S, the bottom piece 120_B, and the frame 120_F of the case 120 may contact the magnetic structure 130. The term “contact,” “contacting,” “contacts,” or “in contact with,” as used herein, refers to a direct connection (i.e., touching) unless the context clearly indicates otherwise.

The case 120 may include two side walls 120_S opposite each other (e.g., to have internal surfaces facing each other and external surfaces facing away from each other). The bottom piece 120_B of the case 120 may be a bottom sheet or bottom plate, and may include a first lower portion 120_B1 (e.g., a lowermost portion) and a second lower portion 120_B2. The bottom piece 120_B may also may have two horizontal bottom portions, one horizontal top portion, and two connecting portions 120_B3 extending partly vertically to connect each horizontal bottom portion with the horizontal top portion. A bottom, or lower, surface of the bottom piece 120_B may for a lower surface of the case 120. The side walls 120_S and the bottom piece 120_B of the case 120 are connected. In some exemplary embodiments, the frame 120_F may be disposed between each side wall 120_S and the bottom piece 120_B of the case 120. The case 120 may further include a back wall, or rear wall 120_R connected to the frame and connected to the side walls 120_S and the bottom piece 120_B, and a front wall (which has been omitted in the cross-sectional perspective view of FIG. 7). The back wall 120_R may include a lower portion at the same height as the side walls 120_S and the front wall, and an additional upper portion above the height of the side walls 120_S and the front wall and that includes the coupling grooves 110. The lower portion of the back wall 120_R may have a greater thickness (e.g., in the D1 direction) than the upper portion of the back wall 120_R. The back wall 120_R may have an internal facing surface and an external facing surface.

The bottom piece 120_B of the case 120 may surround the upper portion of the rail 40. Specifically, the second lower portion 120_B2 combined with the connecting portions 120_B3 may surround the upper portion of the rail 40. The second lower portion 120_B2 combined with the connecting portions 120_B3 may have a trapezoidal shape. However, this shape is not limited thereto. For example, the second lower portion 120_B2 combined with the connecting portions 120_B3 may have a shape corresponding to the upper portion of the rail 40, and may depend on the shape of the upper portion of the rail. The first lower portion 120_B1 may be disposed on both sides of the connecting portions 120_B3. The first lower portion 120_B1 may be disposed on both sides (e.g., opposite sides) of the upper portion of the rail 40.

The frame 120_F of the case 120 may be formed along the bottom piece 120_B of the case 120. The frame 120_F of the case 120 may be formed on a lower portion of the side walls 120_S of the case 120 and on a lower portion of the back wall 120_R and front wall of the case 120. The frame 120_F of the case 120 may be designed to support a load of the magnetic structure 130.

In some exemplary embodiments, a thickness of the bottom piece 120_B of the case 120 may be smaller than a thickness of the frame 120_F of the case 120. Here, the thickness of the frame 120_F of the case 120 may be a thickness in the second direction D2 and/or the third direction D3. The thickness of the lower surface 120_B of the case 120 may be a thickness in the third direction D3. The thickness of the bottom piece 120_B of the case 120 may be, for example, 0.1 mm or less. As the thickness of the bottom piece 120_B of the case 120 becomes thinner, a magnetic force of the magnetic structure 130 attracting foreign substances may be improved.

In some exemplary embodiments, a thickness of each side wall 120_S of the case 120 may be greater than the thickness of the bottom piece 120_B of the case 120. However, the present disclosure is not limited thereto. Here, the thickness of the side walls 120_S of the case 120 may be a thickness in the second direction D2. In another exemplary embodiment, the thickness of each side wall 120_S of the case 120 may be the same as that of the bottom plate 120_B of the case 120 and may be smaller than the thickness of the frame 120_F of the case 120.

The magnetic structure 130, which may be a magnet, may have a shape corresponding to the case 120 (e.g., so that its outer surfaces conform to and contact inner surfaces of the case 120). The magnetic structure 130 may be seated on the case 120. The magnetic structure 130 may be inserted into the case 120 in the third direction D3. A lower portion of the magnetic structure 130 may contact the bottom piece 120_B of the case 120. External surfaces of the magnetic structure 130 that conform to the frame 120_F of the case may form a groove into which the frame 120_F fits. The external surfaces of the magnetic structure 130 may contact internal surfaces of the frame 120_F. The magnetic structure 130 may be disposed under the cartridge 20. Therefore, the magnetic structure 130 may overlap the cartridge 20 in the third direction D3.

The magnetic structure 130 may include a material having a magnetic force. For example, the magnetic structure may be a permanent magnet made of a ferromagnetic material. Foreign substances may be attached to the case 120 by the magnetic force of the magnetic structure 130. For example, foreign substances such as iron (Fe) may be attached to a lower surface of the bottom piece 120_B and/or outer surfaces of the side walls 120_S of the case 120. Due to the magnetic force, the foreign substances are not separated from the case 120 while the substrate treating apparatus moves.

In some exemplary embodiments, the magnetic structure 130 may include a body 131 and a protrusion 132. The protrusion 132 may be disposed under the body 131. The protrusion 132 may be designed to contact the bottom piece 120_B of the case 120. Specifically, the protrusion 132 may contact the first lower portion 120_B1, the second lower portion 120_B2, and the connecting portions 120_B3 of the bottom piece 120_B, and the frame 120_F of the case 120 may surround the protrusion 132. Accordingly, the protrusion 132 may be fitted into and coupled to an empty space of the frame 120_F.

Using the magnetic force of the magnetic structure 130, the foreign substance collecting unit 10 may adsorb foreign substances. In one embodiment, the foreign substances may be attached to a lower surface of the bottom piece 120_B of the case 120 by the magnetic force of the magnetic structure 130. For example, because the bottom piece 120_B is closest to the rail 40, and because the bottom piece 120_B of the case is thin, foreign substances may attach to the lower surface of the bottom piece 120_B. However, in some embodiments, additional foreign substances may attach to side walls 120_S, the back wall 120_R, or the front wall of the case 120. Even when the foreign substance collecting unit 10 is detached from the cartridge 20, the foreign substances are attached to the bottom piece 120_B (and possibly front and back walls and side walls) of the case 120 by the magnetic structure 130. Therefore, after the foreign substance collecting unit 10 is detached from the cartridge 20, the foreign substances may be easily removed.

The upper cover 140 may be disposed on the magnetic structure 130 and the case 120. The upper cover 140 may enclose and fix the magnetic structure 130. The upper cover 140 may prevent the magnetic structure 130 from being separated. The upper cover 140 may be coupled to the case 120 by a coupling member such as a screw.

Referring to FIG. 9, in one embodiment, the magnetic structure 130B may include a body 133 and a magnet part 134.

The magnet part 134 may be disposed along an outer side of the body 133. The magnet part 134 may be a part in contact with the side walls 120_S and the bottom piece 120_B of the case 120. The magnet part 134 may include a magnetic material. The magnet part 134 may include a plurality of magnets. The magnet part 134 may include, for example, a plurality of bar magnets. On the other hand, the body 133 may include a non-magnetic material. The body 133 may include a material that may be easily processed into a shape. In addition, the body 133 may include a material having a lower density than the magnet part 134.

Although not illustrated, in some exemplary embodiments, the frame 120_F of the case 120 may not exist. In this case, the magnetic structure 130 may not include the protrusion 132.

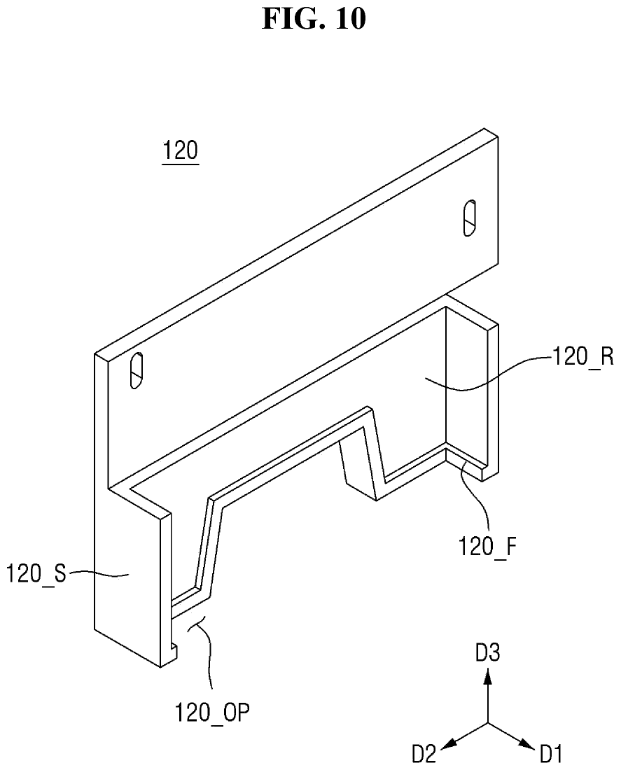

FIG. 10 is a cross-sectional perspective view for describing the foreign substance collecting unit used in the substrate treating apparatus according to some exemplary embodiments. For reference, FIG. 10 is a view taken along line A-A of FIG. 7. For convenience of explanation, points different from those described with reference to FIGS. 4 to 8 will be mainly described.

Unlike FIG. 7, the case 120 may not have the bottom piece 120_B. The case 120 may include an opening 120_OP formed at a lower portion thereof. The magnetic structure 130 may be seated on the case 120. The protrusion 132 of the magnetic structure 130 may be exposed through the opening 120_OP of the case 120. That is, other components may not be disposed between the protrusion 132 and the rail 40. Since the lower portion of the magnetic structure 130 is not covered by the case 120, the magnetic force of the magnetic structure 130 attracting foreign substances may be improved.

Unlike illustrated, a portion of the bottom piece 120_B of the case 120 may exist. For example, the first lower portion 120_B1 of FIG. 7 may exist and the second lower portion 120_B2 (and in some embodiments the connecting portions 120_B3) may not exist. In this case, the opening 120_OP of the case 120 may be a portion corresponding to the second lower portion 120_B2 (and in some embodiments the connecting portions 120_B3) of FIG. 7.

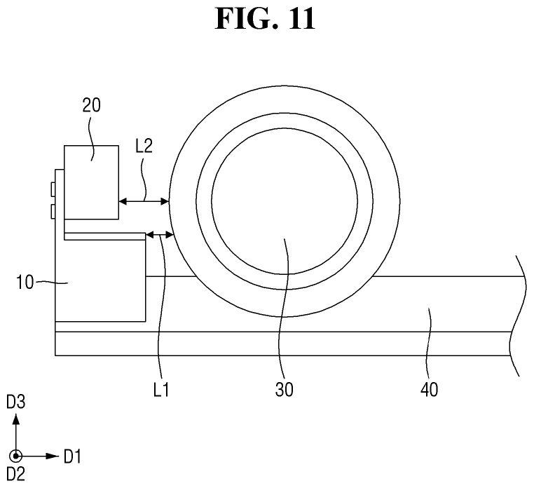

FIG. 11 is a view for describing a substrate treating apparatus according to some exemplary embodiments. For convenience of explanation, points different from those described with reference to FIGS. 4 to 8 will be mainly described. The features described in connection with FIG. 11 may be included in any of the other embodiments described herein.

The foreign substance collecting unit 10 may be spaced apart from the roller 30 by a first distance L1 in the first direction D1. Here, the first distance L1 may be the closest distance between the foreign substance collecting unit 10 and the roller 30. The cartridge 20 may be spaced apart from the roller 30 by a second distance L2 in the first direction D1. Here, the second distance L2 may be the closest distance between the cartridge 20 and the roller 30. The first distance L1 may be smaller than the second distance L2.

Compared to FIG. 5, widths of the side walls 120_S and the bottom piece 120_B of the case 120 in the first direction DI may be large. The magnetic structure 130 may be formed to be in contact with the side walls 120_S and the bottom piece 120_B of the case 120. Therefore, an area where the magnetic structure 130 and the rail 40 overlap in the third direction D3 is wide, and an area capable of collecting foreign substances may increase.

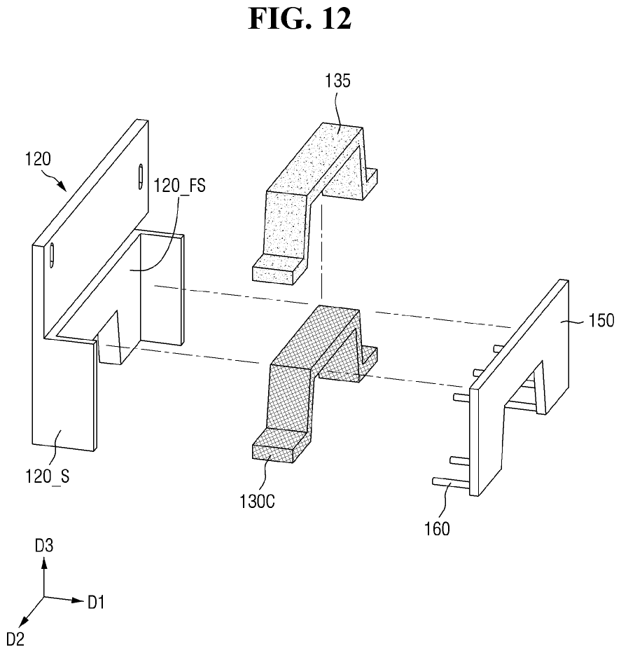

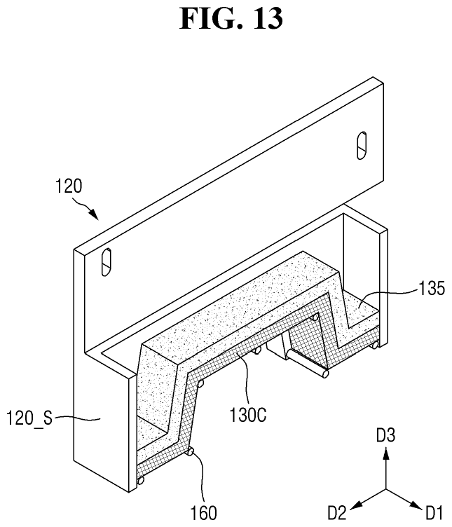

FIGS. 12 and 13 are views for describing the foreign substance collecting unit used in the substrate treating apparatus according to some exemplary embodiments. For convenience of explanation, points different from those described with reference to FIGS. 4 and 5 will be mainly described.

Referring to FIGS. 12 and 13, in some exemplary embodiments, the foreign substance collecting unit 10 may include a case 120, a magnet net 130C, a first fixing member 135, a rear cover 150, and a support member 160. Terms such as front and rear may be used interchangeably depending on the point of view of the components being described.

The case 120 may include a front wall 120_FS and side walls 120_S. The rear cover 150 may face an inner surface of the front wall 120_FS of the case 120.

The support member 160 may be formed on the rear cover 150. The support member 160 may be, for example, a pin (or a plurality of pins). Items described here in the singular may apply to items shown in the figures or described elsewhere in plural. However, the support member 160 is not limited to a pin. In another example, the support member 160 may be a thin plate. In this case, the support member 160 may be similar to the bottom piece 120_B of the case 120 of FIG. 7. In the following, a description is made under the assumption that the support member 160 is a pin.

The number of support members 160 may be plural. The support member 160 may be coupled to the front wall 120_FS of the case 120 (e.g., at an inner surface of the front wall 120_FS). The support member 160 may be coupled to the rear cover 150. The support member 160 may be coupled to the front wall 120_FS and the rear cover 150 of the case 120 to support the magnet net 130C. The respective support members 160 may be spaced apart from each other. An empty space may exist between the support members 160. The magnet net 130C may be exposed between and supported by the support members 160.

The magnet net 130C may be disposed on the support member 160. The first fixing member 135 may be disposed on the magnet net 130C. The first fixing member 135 may be conformably formed on the magnet net 130C and may form a cover on magnet net 130C. The magnet net 130C may be a magnetic structure such as a metal net having a magnetic force. The magnet net 130C may be easily deformed in shape. The first fixing member 135, which may have a bent plate shape, may prevent the separation of the magnet net 130C and hold the shape of the magnet net 130C.

The magnet net 130C may be disposable. Due to a magnetic force of the magnet net 130C, foreign substances may be adsorbed to the magnet net 130C. Since the magnet net 130C is exposed between the support members 160, the foreign substances may be directly adsorbed to the magnet net 130C. In this case, the rear cover 150 of the foreign substance collecting unit 10 is separated. Subsequently, the first fixing member 135 may be separated, and the magnet net 130C to which the foreign substances are attached may be removed and disposed of and be replaced with a new magnet net 130C. The foreign substances may be conveniently removed from the foreign substance collecting unit 10.

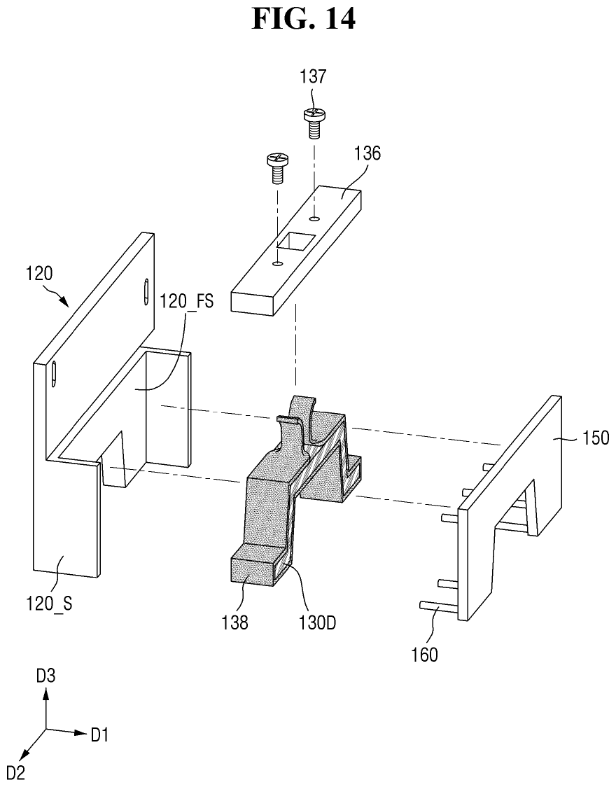

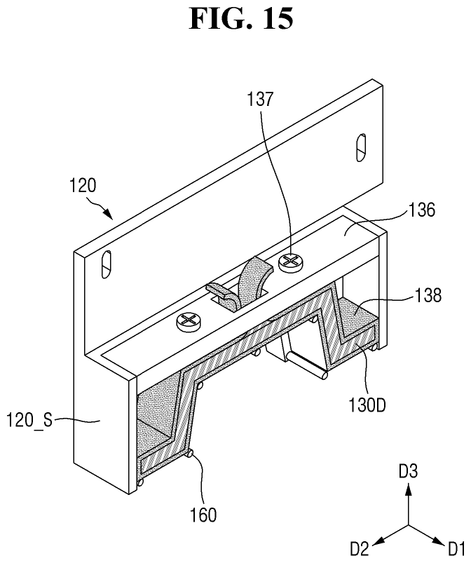

FIGS. 14 and 15 are views for describing the foreign substance collecting unit used in the substrate treating apparatus according to some exemplary embodiments. For convenience of explanation, points different from those described with reference to FIGS. 4 and 5 will be mainly described.

Referring to FIGS. 14 and 15, in some exemplary embodiments, the foreign substance collecting unit 10 may include a case 120, a magnetic material 130D, a tape 138, a second fixing member 136, a rear cover 150, and a support member 160.

The case 120 may include a front wall 120_FS and side walls 120_S. The rear cover 150 may face the front wall 120_FS of the case 120.

The support member 160 may be formed on the rear cover 150. The support member 160 may be, for example, a pin. However, the support member 160 is not limited thereto. In another example, the support member 160 may be a thin plate. In this case, the support member 160 may be similar to the bottom piece 120_B of the case 120 of FIG. 7. In the following, a description is made under the assumption that the support member 160 is a pin.

The magnetic material 130D may include a magnetic structure formed of a material such as a permanent magnet having a magnetic force. A portion of the magnetic material 130D may cover the upper portion of the rail 40. Another portion of the magnetic material 130D may be disposed on both sides (e.g., opposite sides) of the upper portion of the rail 40.

The tape 138 may be disposed around the magnetic material 130D, to form a cover on magnetic material 130D and be conformably formed on the magnetic material 130D. The tape 138 may be formed along an outer side surface of the magnetic material 130D. In some exemplary embodiments, the tape 138 may be adhesive. The tape 138 is a replaceable consumable, and therefore may be disposable.

The second fixing member 136 may be disposed on the magnetic material 130D and the tape 138. The second fixing member 136 may include holes and tape fixing screws 137. Both ends of the tape 138 may penetrate through the holes of the second fixing member 136. The tape fixing screw 137 may penetrate through upper surfaces of the second fixing member 136, the tape 138, and the magnetic material 130D to fix the tape 138 onto the magnetic material 130D.

Unlike illustrated, in some exemplary embodiments, the second fixing member 136 may be coupled to the case 120. In this case, the second fixing member 136 may not include the tape fixing screws 137. The second fixing member 136 may be coupled to the case 120 to prevent the tape 138 from being separated from the magnetic material 130D.

The number of support members 160 may be plural. The support member 160 may be coupled to the front wall 120_FS of the case 120. The support member 160 may be coupled to the rear cover 150. The support member 160 may be coupled to the front wall 120_FS and the rear cover 150 of the case 120 to support the magnet net 130C. The respective support members 160 may be spaced apart from each other. An empty space may exist between the support members 160. Therefore, the tape 138 may be exposed between the support members 160.

The tape 138 may be disposable. Foreign substances may be adsorbed to the tape 138 by a magnetic force of the magnetic material 130D. Since the tape 138 surrounding the magnetic material 130D is exposed between the support members 160, the foreign substances may be directly attached onto the tape 138. In this case, the rear cover 150 and the second fixing member 136 of the foreign substance collecting unit 10 are separated. Subsequently, the tape 138 to which the foreign substances are attached is removed from the magnetic material 130D and is replaced with a new tape 138. The foreign substances may be conveniently removed from the foreign substance collecting unit 10.

In concluding the detailed description, those skilled in the art will appreciate that many variations and modifications may be made to the preferred embodiments without substantially departing from the principles of the present inventive concept. Therefore, the disclosed preferred embodiments of the invention are used in a generic and descriptive sense only and not for purposes of limitation.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

What is claimed is:

1. A substrate treating apparatus comprising:
a roller configured to be disposed on a rail extending in a first direction, and attached to a side surface of a carrier unit to move along the rail; and
a foreign substance collecting unit installed on the side surface of the carrier unit, moving together with the roller, and configured to be spaced apart from the rail when the roller is disposed on the rail,
wherein the foreign substance collecting unit includes a magnetic structure for adsorbing magnetic foreign substances using a magnetic force, and a case surrounding the magnetic structure.

2. The substrate treating apparatus of claim 1, further comprising a cartridge installed on the side surface of the carrier unit and providing lubricant,
wherein the foreign substance collecting unit is coupled to the cartridge, and
wherein the magnetic structure is disposed between the cartridge and the rail when the roller is disposed on the rail.

3. The substrate treating apparatus of claim 2, wherein the foreign substance collecting unit includes a coupling groove for adjusting a height at which the foreign substance collecting unit is coupled to the cartridge.

4. The substrate treating apparatus of claim 1, wherein the case includes side walls and a bottom piece, and
a thickness of the bottom piece of the case is smaller than a thickness of the side walls of the case.

5. The substrate treating apparatus of claim 1, wherein the case includes a frame disposed on a bottom piece, and
a thickness of the frame is greater than a thickness of the bottom piece.

6. The substrate treating apparatus of claim 5, wherein a thickness of each side wall is smaller than the thickness of the frame.

7. The substrate treating apparatus of claim 5, wherein the magnetic structure includes a protrusion,
the protrusion is formed at a lower surface of the bottom piece of the case, and
the frame of the case surrounds the protrusion.

8. The substrate treating apparatus of claim 1, wherein a lower surface of the case surrounds an upper portion of the rail.

9. A substrate treating apparatus comprising:
a carrier unit configured to adsorb a substrate and configured to connect to a rail for moving the substrate to a polishing pad;
a roller installed on a side surface of the carrier unit and configured to move along the rail;
a cartridge installed on the side surface of the carrier unit and configured to provide lubricant to the roller; and
a foreign substance collecting unit coupled to the cartridge and including a magnetic structure for adsorbing magnetic foreign substances using a magnetic force, and a case surrounding the magnetic structure.

10. The substrate treating apparatus of claim 9, wherein the magnetic structure includes a plurality of magnets disposed on a lower portion.

11. The substrate treating apparatus of claim 9, wherein the case includes a rear cover and a support member for supporting the magnetic structure, and
the magnetic structure includes a magnet net disposed on the support member and a first fixing member disposed on the magnet net.

12. The substrate treating apparatus of claim 9, wherein the case includes a rear cover and a support member for supporting the magnetic structure, and
the magnetic structure includes a magnetic material disposed on the support member, a tape surrounding the magnetic material, and a second fixing member for fixing the tape.

13. The substrate treating apparatus of claim 9, wherein the case includes an opening formed at a lower portion.

14. The substrate treating apparatus of claim 9, wherein the case includes side walls and a bottom piece, and
a thickness of the bottom piece of the case is smaller than a thickness of each side wall of the case.

15. The substrate treating apparatus of claim 14, wherein a thickness of the bottom piece of the case is 0.1 mm or less.

16. The substrate treating apparatus of claim 9, wherein the cartridge includes a cartridge cover and a coupling screw coupling the cartridge cover to the cartridge, and
the coupling screw couples the cartridge cover and the foreign substance collecting unit together to the cartridge.

17. The substrate treating apparatus of claim 9, wherein the case includes a first lower portion disposed on a top surface of an upper portion of the rail and a second lower portion disposed on opposite sides of the upper portion of the rail.

18. The substrate treating apparatus of claim 9, wherein a distance between the roller and the foreign substance collecting unit is smaller than a distance between the cartridge and the roller.

19. A substrate treating system comprising:
a polishing part including a polishing pad disposed on a polishing unit;
a carrier unit including a carrier head adsorbing a substrate and moving the substrate to the polishing pad;
a rail installed in the polishing part;
a roller installed on a side surface of the carrier unit to move along the rail;
a cartridge installed on the side surface of the carrier unit and providing lubricant to the roller; and
a foreign substance collecting unit coupled onto the cartridge and including a magnetic structure for adsorbing foreign substances using a magnetic force and a case surrounding the magnetic structure,
wherein a lower surface of a bottom piece of the case surrounds an upper portion of the rail.

20. The substrate treating system of claim 19, wherein the case includes a frame disposed on the bottom piece, and
a thickness of the frame is greater than a thickness of the bottom piece.
